(19) United States
(12) Patent Application Publication
(10) Pub. No.: US 2021/0296388 A1
(43) Pub. Date: Sep. 23, 2021

(54) IMAGE SENSOR DEVICE

(71) Applicant: SK hynix Inc., Gyeonggi-do (KR)

(72) Inventors: Sung Ryong LEE, Gyeonggi-do (KR); Hyungjoon SHIM, Gyeonggi-do (KR)

(21) Appl. No.: 16/990,699

(22) Filed: Aug. 11, 2020

(30) Foreign Application Priority Data
Mar. 20, 2020 (KR) 10-2020-0034264

(51) Int. Cl. H01L 27/146

(52) U.S. Cl. CPC H01L 27/14636; H01L 27/1464

(57) ABSTRACT

An image sensor device is disclosed, which blocks noise of a pad area and minimizes parasitic capacitance of the pad area. The image sensor device includes a substrate including a first surface and a second surface that are arranged to face each other, a pad disposed over the first surface of the substrate, and a noise blocking area formed to overlap with the pad in a first direction, and formed in the substrate.

### CROSS-REFERENCE TO RELATED APPLICATION

This patent document claims the priority and benefits of Korean patent application No. 10-2020-0034264, filed on Mar. 20, 2020, which is hereby incorporated in its entirety by reference.

### TECHNICAL FIELD

The present invention relates generally to image sensor technology and, more particularly, to a technology for blocking the noise or minimizing the parasitic capacitance of a pad area of an image sensor.

### BACKGROUND

An image sensor converts an optical image into electrical signals. Recently, because of the increased research development in the computer and communication industries, demand for high-quality, high-performance image sensors is rapidly increasing in various applications and fields, such as, for example, digital cameras, camcorders, personal communication systems (PCSs), game consoles, surveillance cameras, medical micro-cameras, and the like.

Specifically, MOS image sensors can be driven more easily, and can be implemented using many more scanning schemes. The MOS image sensor may include one or more photoelectric conversion elements configured to sense the magnitude of incident light and a multilayer metal line layer configured to output light signals stored in the photoelectric conversion elements. However, the incident light may be reflected by the metal line layer, and may be absorbed by an interlayer insulation film, resulting in reduction in sensitivity. In addition, the reflected light may be absorbed into contiguous (or adjacent) pixels, resulting in occurrence of crosstalk.

### SUMMARY

Various embodiments of the disclosed technology relate to an image sensor device for reducing noise of a pad area and parasitic capacitance of the pad area. The image sensor may be a BSI image sensor.

In accordance with an embodiment of the disclosed technology, an image sensor device may include a substrate including a first surface and a second surface that are arranged to face each other, a pad disposed over the first surface of the substrate, and a noise blocking area formed to overlap with the pad in a first direction perpendicular to the first surface, and formed in the substrate.

In accordance with another embodiment of the disclosed technology, an image sensor device may include a substrate in which a pad area and a circuit area located contiguous to the pad area are defined, a pad disposed over a first surface of the substrate in the pad area, and a noise blocking area formed in the substrate below the pad in the pad area.

In accordance with another embodiment of the disclosed technology, an image sensor device may include a noise blocking area formed in a substrate, a pad disposed over the noise blocking area, a conductive film disposed between the noise blocking area and the pad, and a through silicon via (TSV) electrically coupled to the pad through the conductive film.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a schematic plan view illustrating an example of an image sensor device based on some implementations of the disclosed technology.

FIG. 2 is a block diagram illustrating an example of some constituent elements of an image sensor device based on some implementations of the disclosed technology.

FIGS. 3 and 4 are cross-sectional views illustrating examples of the image sensor device shown in FIG. 1 based on some implementations of the disclosed technology.

FIG. 5 is a cross-sectional view illustrating another example of the image sensor device shown in FIG. 1 based on some implementations of the disclosed technology.

FIG. 6 is a cross-sectional view illustrating still another example of the image sensor device shown in FIG. 1 based on some implementations of the disclosed technology.

### DETAILED DESCRIPTION

Various implementations and examples of an image sensor device are provided that address one or more limitations and disadvantages of the related prior art. Various implementations of the disclosed technology are directed to an image sensor device capable of reducing pad area noise and parasitic capacitance and for addressing the aforementioned issues of existing technology.

Reference will now be made in detail to embodiments of the disclosed technology, examples of which are illustrated in the accompanying drawings. Wherever possible, the same reference numbers are used throughout the drawings to refer to the same or like portions.

Advantages and features of the disclosed technology and a method of achieving the advantages and features of the disclosed technology will be clearly understood from embodiments described hereinafter in conjunction with the accompanying drawings. However, the disclosed technology is not limited to the following embodiments and may be realized in various different forms. These embodiments are provided only to clearly describe the technology and for a person having ordinary skill in the art to which the disclosed technology pertains to understand the disclosure. That is, the disclosed technology is defined only by the claims. In the drawings, the sizes or relative sizes of layers and areas may be exaggerated for clarity of description.

The terminology used herein is for the purpose of describing particular embodiments only and is not intended to be limiting of the disclosed technology. As used herein, the singular forms are intended to include the plural forms as well, unless the context clearly indicates otherwise. It will be further understood that the terms “comprises,” “comprising,” “includes,” and “including” when used in this specification, specify the presence of stated constituent elements, steps, operations, and/or components, but do not preclude the presence or addition of one or more other constituent elements, steps, operations, and/or components thereof. The term “and/or” may include a combination of a plurality of items or any one of a plurality of items. The same reference numbers will be used throughout this specification to refer to the same or like constituent elements.

In description of the disclosed technology, the terms “first”, “second” and the like may be used to describe various elements, components, and/or sections, but the elements, components, and/or sections are not limited by these terms. These terms may be used to distinguish one component, one constituent element, or one section from another component, another constituent element, or another section. Therefore, a first element, a first constituent element, or a first section may also be called a second element, a second constituent element, or a second section without departing from the scope of the disclosed technology.

When an element or a layer is referred to as being “on” another element or another layer, it can be directly on the element or the layer, or one or more intervening elements or layers may also be present. In contrast, when an element or a layer is referred to as being “directly on” another element or another layer, it means that no intervening elements or layers are present. The term “and/or” may include a combination of a plurality of items or any one of a plurality of items.

Spatially relative terms such as “below,” “beneath/” “lower,” “above,” or “upper” may be used herein to describe one element's relationship to another element as illustrated in the drawings. It will be understood that spatially relative terms are intended to encompass different orientations of the elements during the use or operation of the elements in addition to the orientation depicted in the drawings. Wherever possible, the same reference numbers will be used throughout the specification to refer to the same or like elements.

Furthermore, the embodiments described herein may be understood with reference to cross-sectional views and plan views, that is, diagrams of the disclosed technology. Accordingly, forms of the example diagrams may be changed by fabrication technology and/or tolerance. Accordingly, the embodiments of the disclosed technology are not limited to the illustrated specific forms, but may include changes in forms generated according to a fabrication process. Accordingly, areas illustrated in the drawings have schematic attributes, and the shapes of the illustrated areas are intended to illustrate a specific form of an area of the element (or device) but are not intended to limit the scope of the disclosed technology.

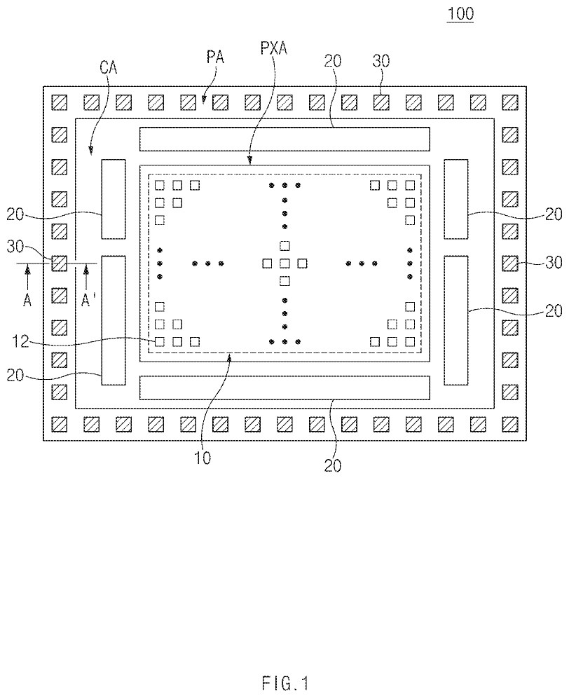

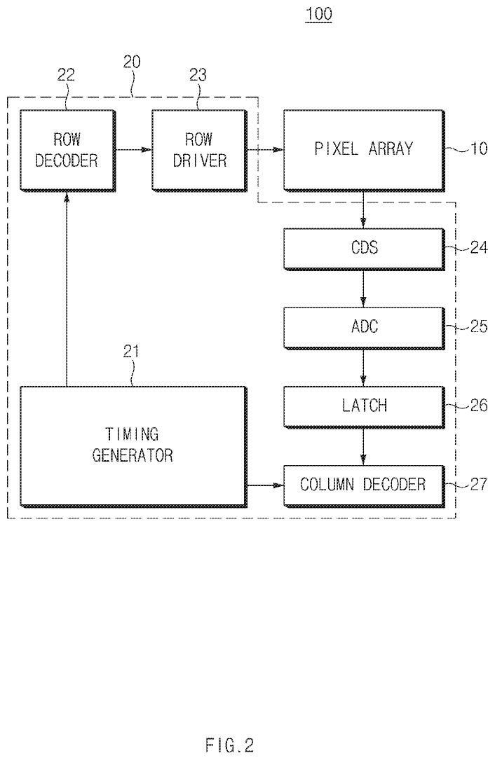

FIG. 1 is a schematic plan view illustrating an example of an image sensor device 100 based on some implementations of the disclosed technology. FIG. 2 is a block diagram illustrating an example of some constituent elements of the image sensor device 100 based on some implementations of the disclosed technology.

Referring to FIGS. 1 and 2, the image sensor device 100 may include a pixel area PXA, a circuit area CA, and a pad area PA.

The pixel area PXA may include a pixel array 10 in which a plurality of unit pixels 12 is arranged in a matrix shape. Each of the plurality of unit pixels 12 may include a photoelectric conversion element (not shown).

The circuit area CA may be formed around the pixel area PXA, and may include a plurality of circuits 20. The circuit area CA may include a plurality of CMOS transistors (not shown). The circuit area CA may transmit a predetermined signal to each unit pixel 12 of the pixel array 10. The circuit area CA may control an output signal at each unit pixel 12. The pad area PA may include a plurality of pads 30 located contiguous to the circuit area CA. The plurality of pads 30 may be spaced apart from each other in a single file in the pad area PA as shown in FIG. 1 for example. However, the invention may not be limited in this way. For example, in other implementations of the invention a double file of pads 30 may be employed.

Referring to FIG. 1, the circuit area CA may be defined to surround the pixel area PXA, and the pad area PA may be defined to surround the circuit area CA, without being limited thereto. For example, in variations of the described implementation, the circuit area CA may not surround the pixel area PXA. Also, the pad area PA may be formed at fewer than all the sides of the circuit area. For example, the pad area may be formed only at three sides, or only at two sides or only at one side of the circuit area CA. In an implementation, for example, the circuit area CA may not surround the pixel area PXA and the pad area PA may be formed only at one side of the circuit area CA.

Referring to FIG. 2, one or more of the plurality of circuits 20 formed in the circuit area CA may include a timing generator 21, a row decoder 22, a row driver 23, a correlated double sampler (CDS) circuit 24, an analog-to-digital converter (ADC) circuit 25, a latch circuit 26, and a column decoder 27.

The pixel array 10 included in the pixel area PXA may receive a plurality of drive signals, for example, a row selection signal, a reset signal, a charge transfer signal, etc., from the row driver 23, and may be driven by the received drive signals. In addition, electrical signals acquired by photoelectric conversion in the pixel array 10 may be provided to the CDS circuit 24.

The timing generator 21 may transmit a timing signal and control signals to the row decoder 22 and the column decoder 27. Upon receiving the decoded result from the row decoder 22, the row driver 23 may transmit a plurality of drive signals needed to drive the plurality of unit pixels 12 to the pixel array 10 of the pixel area PXA. When the plurality of unit pixels 12 is arranged in a matrix, the row driver 23 may provide a drive signal for each row of the matrix.

The CDS circuit 24 may receive output signals from the pixel array 10 of the pixel area PXA, and may hold and sample the received output signals. That is, the CDS circuit 24 may perform double sampling of a signal level caused by each output signal and a specific noise level, and may thus output a level difference corresponding to a difference between the noise level and the signal level.

The ADC circuit 25 may convert an analog signal corresponding to the level difference into a digital signal, and may thus output the digital signal. The latch circuit 26 may latch digital signals received from the ADC circuit 25 and may output the latched signals sequentially to an image signal output circuit (not shown) in response to the decoded result acquired by the column decoder 27.

In some implementations, the image sensor 100 may be a backside illuminated (BSI) image sensor. In addition, light may be incident upon the pixel area PXA from the same surface as an exposure surface on which the plurality of pads 30 is exposed outside from among a plurality of exposure surfaces of the image sensor 100.

The plurality of pads 30 may be electrically coupled to a plurality of wells formed in the circuit area CA through connection lines. In some implementations, the plurality of pads 30 may be formed of metal, metal nitride, or a combination thereof. In some implementations, the plurality of pads 30 formed in the pad area PA may transmit and receive electrical signals to and from an external device. In other implementations, the plurality of pads 30 may serve to transfer a driving power source, such as a power-supply voltage or a ground voltage received from the outside, to circuits included in the circuit area CA through a connection line.

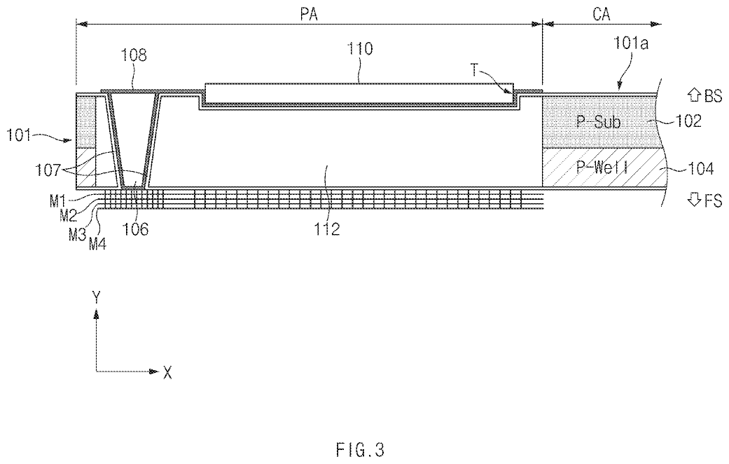

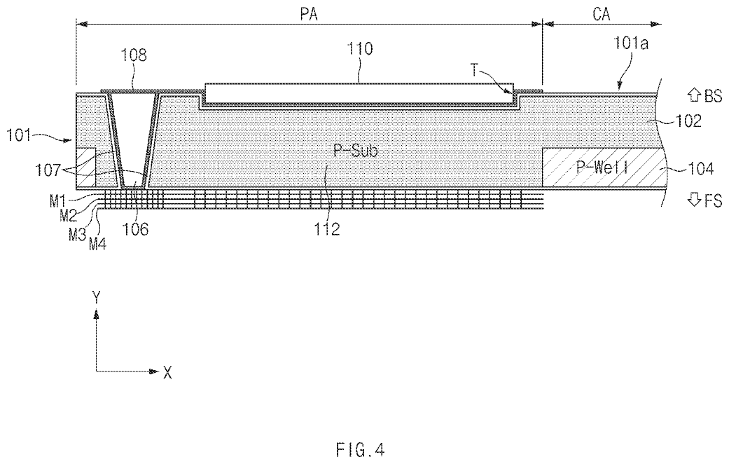

FIGS. 3 and 4 are cross-sectional views illustrating examples of the image sensor device 100 shown in FIG. 1 based on some implementations of the disclosed technology. In more detail, FIGS. 3 and 4 are cross-sectional views illustrating the image sensor device 100 taken along the line A-A′ shown in FIG. 1.

Referring to FIGS. 3 and 4, a circuit area CA and a pad area PA may be defined in a substrate 101. For convenience of description, the substrate of the pad area PA including a pad 110 will hereinafter be denoted by reference number “101”, and the substrate of the circuit area CA may hereinafter be also denoted by reference number “101a”.

The substrate 101 may include a front side (FS) and a back side (BS) that are arranged to face each other. One side of the substrate 101 can be defined as the front side (FS) and the other side of the substrate 101 can be defined as the back side (BS), without being limited thereto. For example, unit elements may be formed over the front side (FS) of the substrate 101, and light may be emitted to the back side (BS) of the substrate 101.

The substrate 101 may be any suitable substrate. For example, the substrate 101 may be a P-type bulk substrate. Also, for example, the substrate 101 may be an N-type bulk substrate. The substrate may include an epitaxial layer growing on the bulk substrate. The epitaxial layer may be a P-type epitaxial layer. The epitaxial layer may be an N-type epitaxial layer. For example, the substrate may be a substrate formed by growing a P-type or N-type epitaxial layer on an N-type bulk substrate or on a P-type bulk substrate. The substrate 101 may be formed of an organic plastic substrate rather than a semiconductor substrate. Examples of organic plastic substrates may include substrates made of organic small molecules or polymers. Organic small molecules may include, for example, polycyclic aromatic compounds, such as pentacene, anthracene, and rubrene. Suitable polymers may include, for example, fluoropolymers such as PVDF (polyvinylidene fluoride) or PVDF copolymers such as PVDF copolymers with trifluoroethylene. In some implementations, a P well 104 may be formed at the front side (FS) and contained in the P-type substrate 101a.

A plurality of lines M1˜M4 for signal transmission may be disposed over the front side (FS) of the substrate 101. The plurality of lines M1 M4 may be sequentially stacked in an interlayer insulation film (not shown). In this case, each of the plurality of lines M1˜M4 may include metal. For example, the plurality of lines M1˜M4 may include copper (Cu), platinum (Pt), tungsten (W), aluminum (Al), an alloy layer formed of the above materials, and the like. The number of layers of the plurality of lines M1˜M4 and structure types of the plurality of lines M1˜M4 may not be limited thereto, and the plurality of lines M1˜M4 may be formed in various numbers of layers and various types of structures according to device design methods.

A conductive film 108 may be disposed over the back side (BS) of the substrate 101. The conductive film 108 may be formed over the substrate 101. The conductive film 108 may be formed to cover a top surface of the back side (BS) of the substrate 101. The conductive film 108 may be formed to be longer than the pad 110 in an X-axis direction parallel to the substrate 101. The conductive film 108 may be formed to in direct contact with the top surface of the back side (BS) of the substrate 101. The conductive film 108 may be formed to be thinner than the pad 110 in a Y-axis direction. The Y-axis may be vertical to the X-axis. The conductive film 108 may extend to cover at least partially both sides of the pad 110, and may be coupled to a top surface of a through silicon via (TSV) 106. The conductive film 108 may be disposed over a trench (T) formed to expose some parts of the back side (BS) of the substrate 101.

The conductive film 108 may be formed to prevent the substrate 101 from being damaged in a patterning process needed to form the pad 110. For example, the conductive film 108 may include metal, such as, for example, tungsten (W).

The pad 110 may be disposed over the conductive film 108 of the substrate 101. In an embodiment, the pad 110 may be formed directly on the conductive film 108 of the substrate 101. The pad 110 may be a constituent element corresponding to the pad 30 shown in FIG. 1. The pad 110 may be formed along a top surface and the sidewalls of the conductive film 108 which are formed conformally in the trench (T). In addition, the pad 110 and the plurality of lines M1˜M4 may be electrically coupled to each other via the conductive film 108 and the through silicon via (TSV) formed to penetrate the substrate 101. In this case, the pad 110 may include metal materials, for example, aluminum (Al), copper (Cu), etc.

An insulation layer 107 may be formed at sidewalls of the through silicon via (TSV) 106, and may also be formed below the conductive film 108. The insulation layer 107 may be formed as an isolation pattern by which the through silicon via (TSV) 106 and the substrate 101 can be electrically isolated from each other. The insulation layer 107 may be formed to prevent the through silicon via (TSV) 106 and the conductive film 108 from being electrically coupled to (i.e., from being short-circuited to) the substrate 101.

In this case, the insulation layer 107 may be formed of only one insulation material. In another example, the insulation layer 107 may be formed by stacking at least two insulation patterns. The insulation layer 107 may be formed of oxide materials such as silicon oxide and metal oxide, or may be formed of nitride materials such as silicon nitride.

The through silicon via (TSV) 106 may be formed at one side of the substrate 101, and may be formed to penetrate the substrate 101. A bottom surface of the through silicon via (TSV) 106 may be in contact with the plurality of lines M1˜M4. The through silicon via (TSV) 106 may have a sidewall slope in a manner that an inner width of the through silicon via (TSV) 106 becomes smaller in a downward direction from the back side (BS) of the substrate 101. Alternatively, although not shown in the drawings, the through silicon via (TSV) 106 may also have a vertical sidewall slope.

A contact hole (not shown) penetrating the substrate 101 may be formed, and the contact hole (not shown) may be filled with a conductive material, resulting in formation of the through silicon via (TSV) 106. The through silicon via (TSV) 106 may also be formed to fill the contact hole (not shown), and may also be conformally formed along sidewalls of the contact hole. The through silicon via (TSV) 106 may be formed in any shape in which the conductive film 108 can be easily coupled to the plurality of lines M1˜M4.

The image sensor 100 based on some implementations of the disclosed technology may include a noise blocking area 112 in the substrate 101 disposed below the pad 110. That is, the image sensor 100 based on some implementations of the disclosed technology may form a fully-depleted noise blocking area 112 that is not doped in the substrate 101 disposed below the pad 110.

Generally, the circuit area CA may not be disposed in a lower area of the pad 110 so as to prevent physical damage, and the same type of conductive materials as in the substrate 101 may be disposed in the lower area of the pad 110. In this case, parasitic capacitance may be formed between the pad 110 and the substrate 101.

Specifically, in the case of using the backside illuminated (BSI) image sensor, signals applied to the pad 110 may be transferred to lower lines M1˜M4 through the through silicon via (TSV) 106. Therefore, excessive capacitance may be formed between the pad 110 and the substrate 101. When such capacitance between the pad 110 and the substrate 101 increases, transition of one or more input signals may become slower in speed. In addition, when a fast digital transition signal is input to the pad 110, noise may be introduced into the substrate 101 through the pad 110.

The image sensor device based on some implementations of the disclosed technology may include the noise blocking area 112 in the substrate 101, such that the pad 110 and the substrates 101 and 101a can be electrically isolated from each other. As a result, the image sensor device may reduce parasitic capacitance generated between the pad 110 and the substrate 101. In other words, the substrate 101a of the circuit area CA may be implemented by forming a first type conductive (e.g., P-type conductive) well 104 in a first type conductive (e.g., P-type conductive) substrate 102. However, the substrate 101 of the pad area PA may form the noise blocking area 112 having no doped area.

The noise blocking area 112 may serve as a non-conductive area in which electricity does not flow, and may allow a fully depleted area to have a larger thickness, resulting in reduction in capacitance. The thickness of fully depleted area of the noise blocking area 112 may be affected by a doping density of the substrate 101. That is, as the doping density of the substrate 101 is reduced, the fully depleted area of the noise blocking area 112 may gradually increase in thickness and capacitance may be gradually reduced.

Specifically, in the case of using the BSI image sensor, the substrate 101 may be formed to have a very thin thickness, for example, several micrometers (μm). Thus, when the substrate 101 is not doped with any impurities, the lower area of the pad 110 may be formed to be in a fully depleted state.

In some implementations, the noise blocking area 112 may be covered with an implant blocking layer formed to prevent doping of impurities, such that the fully depleted state may be formed in the noise blocking area 112.

As can be seen from FIG. 4, when the P-type substrate 102 is formed to have a sufficiently low density of impurities, the first type conductive (e.g., P-type conductive) well 104 may not be formed in the substrate 101 of the pad area PA. As the density of impurities of the substrate 101 is gradually reduced, the fully depleted layer between the pad 110 and the substrate 101 may gradually increase in size. As a result, when the substrate 101 is formed to have a sufficiently low density of impurities, the entire area of the substrate 101 disposed below the pad 110 may be formed of only the substrate 102, resulting in reduction in parasitic capacitance.

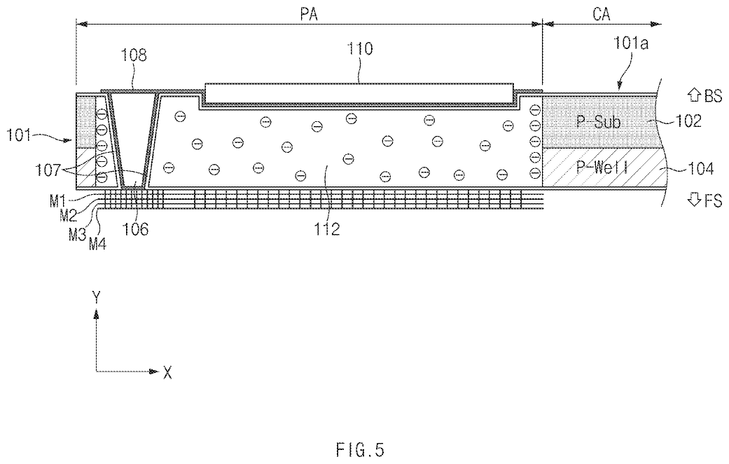

FIG. 5 is a cross-sectional view illustrating another example of the image sensor device shown in FIG. 1 based on some implementations of the disclosed technology. In FIG. 5, the same constituent elements as those of FIG. 3 will be used to refer to the same or like parts for convenience of description and better understanding of the disclosed technology, and as such redundant matters thereof will herein be omitted for brevity.

Referring to FIG. 5, the substrate 101 may be doped with impurities having very low density, such that the noise blocking area 112 may be formed. When a voltage is applied to the pad 110, the substrate 101 may enter a fully depleted state, such that no more current flows into the substrate 101. As a result, a low-impurities density noise blocking area 112 may be formed in the substrate 101, such that the pad 110 and the substrates 101 and 101a can be isolated from each other.

When the substrate 101 is implemented as a P-type substrate, the noise blocking area 112 may be formed through a P-type low-impurities density epitaxial layer. When the substrate 101 is formed to have a very low density of impurities, the substrate 101 may enter the fully depleted state within the operation range (e.g., the range from a ground voltage GND to a power-supply voltage VDD) of the pad 110.

That is, when the substrate 101 disposed below the pad 110 is doped with impurities having very low density, negative (−) ions may be formed such that the noise blocking area 112 having the fully depleted area can be formed. For example, in the case of forming a P-type low-impurities density epitaxial layer in the P-type substrate 101, negative (−) ions may remain unused in the fully depleted area of the noise blocking area 112. In this case, the fully depleted area of the noise blocking area 112 at a boundary surface between the pad area PA and the circuit area CA may operate as a barrier that disturbs movement of noise (electrons).

Impurities implanted into the substrate 101 may be adjusted to have a low density in a manner that the substrate 101 disposed below the pad 110 can enter the fully depleted state. Therefore, coupling between the pad 110 and the substrate 101 is cut off, such that noise and parasitic capacitance to be introduced into the substrate 101 through the pad 110 can be reduced.

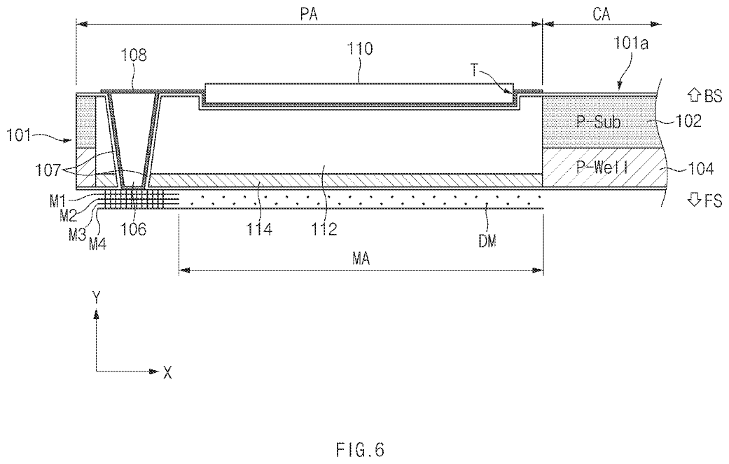

FIG. 6 is a cross-sectional view illustrating still another example of the image sensor device shown in FIG. 1 based on some implementations of the disclosed technology. In FIG. 6, the same constituent elements as those of FIG. 3 will be used to refer to the same or like parts for convenience of description and better understanding of the disclosed technology, and as such redundant matters thereof will herein be omitted for brevity.

Referring to FIG. 6, the plurality of lines M1 M3 may not be formed over the front side (FS) disposed below the substrate 101. That is, when a high-density impurity layer 114 is disposed at the front side (FS) of the substrate 101, the fully depleted area of the noise blocking area 112 may be reduced in size. In this case, although the fully depleted area is formed in the noise blocking area 112, parasitic capacitance may increase by the impurity layer 114.

Thus, the plurality of lines M1 M3 may not be formed in the lower area (i.e., dummy line area MA) of the substrate 101 that overlaps with the pad 110 in the Y-axis direction. That is, the plurality of lines M1˜M4 may be formed below the through silicon via (TSV) 106. However, in a situation in which some lines M4 from among the plurality of lines M1˜M4 remain unused in the line area MA, the plurality of lines M1˜M3 may be removed from the line area MA. When the noise blocking area 112 is incomplete, the impurity layer 114 such as the well 104 may remain. In this case, large capacitance between the impurity layer 114 and the lines M1˜M4 may remain unchanged. However, when some lines M1˜M3 are removed, parasitic capacitance to be generated between the impurity layer 114 and the plurality of lines M1˜M4 can be reduced.

In addition, when some lines M1˜M3 are removed, a step difference may occur between the regions where the plurality of lines M1˜M4 are formed and the regions where the some lines M1˜M3 are not formed. Accordingly, in order to maintain desired flatness of the substrate 101 and the lines M1˜M4 for use in a Chemical Mechanical Polishing (CMP) process or the like, a dummy line (DM) may be additionally formed in a dummy line area MA as necessary. The dummy line area MA may be disposed below the pad 110 and may overlap with the pad 110 in the Y-axis direction. An area below the through silicon via (TSV) 106 and which is adjacent to the dummy line area MA may include plurality of metal lines M1˜M4.

As is apparent from the above description, the image sensor device based on some implementations of the disclosed technology can reduce noise of the pad area and minimize parasitic capacitance of the pad area.

Those skilled in the art will appreciate that the embodiments may be carried out in other specific ways than those set forth herein without departing from the spirit and essential characteristics of the disclosure. The above embodiments are therefore to be construed in all aspects as illustrative and not restrictive. The scope of the disclosure should be determined by the appended claims and their legal equivalents, not by the above description. Further, all changes coming within the meaning and equivalency range of the appended claims are intended to be embraced therein. In addition, those skilled in the art will understand that claims that are not explicitly cited in each other in the appended claims may be presented in combination as an embodiment or included as a new claim by a subsequent amendment after the application is filed.

Although a number of illustrative embodiments have been described, it should be understood that numerous other modifications and embodiments can be devised by those skilled in the art that will fall within the spirit and scope of the principles of this disclosure. Particularly, numerous variations and modifications are possible in the component parts and/or arrangements which are within the scope of the disclosure, the drawings and the accompanying claims. In addition to variations and modifications in the component parts and/or arrangements, alternative uses will also be apparent to those skilled in the art.

What is claimed is:

1. An image sensor device comprising:
a substrate including a first surface and a second surface that are arranged to face each other;
a pad disposed over the first surface of the substrate; and
a noise blocking area formed to overlap with the pad in a first direction perpendicular to the first surface, and formed in the substrate.

2. The image sensor device according to claim 1, wherein the noise blocking area is insulated in a state of being a fully depleted area.

3. The image sensor device according to claim 1, wherein the substrate is a first conductive substrate.

4. The image sensor device according to claim 3, wherein the noise blocking area includes a first conductive epitaxial layer having a low density of impurities.

5. The image sensor device according to claim 1, further comprising:
a conductive film disposed over the first surface of the substrate, and formed to cover a top surface of the substrate at a lower portion of the pad.

6. The image sensor device according to claim 5, wherein the conductive film is formed to extend in a second direction perpendicular to the first direction such that the extended conductive film is longer than the pad.

7. The image sensor device according to claim 5, wherein the conductive film is formed over a trench exposing a part of the substrate.

8. The image sensor device according to claim 7, wherein the pad is formed along a top surface and a side surface of the conductive film formed in the trench.

9. The image sensor device according to claim 5, further comprising:
a through silicon via disposed at one side of the substrate, and formed to penetrate the substrate in the first direction,
wherein the through silicon via is electrically coupled to the pad through the conductive film.

10. The image sensor device according to claim 1, further comprising:
a plurality of lines disposed over the second surface of the substrate, and electrically coupled to the pad through a through silicon via.

11. The image sensor device according to claim 10, wherein:
a line area, which is formed to overlap with the pad and the noise blocking area in the first direction and is formed over the second surface, is configured in a manner that only some lines from among the plurality of lines are included in the line area.

12. The image sensor device according to claim 11, wherein the line area includes a dummy line.

13. An image sensor device comprising:
a substrate in which a pad area and a circuit area located contiguous to the pad area are defined;
a pad disposed over a first surface of the substrate in the pad area; and
a noise blocking area formed in the substrate below the pad in the pad area.

14. The image sensor device according to claim 13, wherein the noise blocking area is insulated in a state of being a fully depleted area.

15. The image sensor device according to claim 13, wherein the substrate is a first conductive substrate.

16. The image sensor device according to claim 15, wherein the noise blocking area includes a first conductive epitaxial layer having a low density of impurities.

17. The image sensor device according to claim 13, further comprising:
a plurality of lines disposed over a second surface of the substrate, and electrically coupled to the pad through a through silicon via.

18. The image sensor device according to claim 17, wherein:
a line area formed over the second surface in the pad area is configured in a manner that only some lines from among the plurality of lines are included in the line area.

19. The image sensor device according to claim 18, wherein the line area includes a dummy line.

20. An image sensor device comprising:
a noise blocking area formed in a substrate;
a pad disposed over the noise blocking area;
a conductive film disposed between the noise blocking area and the pad; and
a through silicon via (TSV) electrically coupled to the pad through the conductive film.
